(19) United States
(12) Patent Application Publication
(10) Pub. No.: US 2024/0282650 A1
(43) Pub. Date: Aug. 22, 2024

(54) SEMICONDUCTOR DEVICE

(71) Applicant: Mitsubishi Electric Corporation, Tokyo (JP)

(72) Inventors: Yuji IWAI, Tokyo (JP); Takahiro KUMA, Tokyo (JP)

(73) Assignee: Mitsubishi Electric Corporation, Tokyo (JP)

(21) Appl. No.: 18/570,678

(22) PCT Filed: Aug. 25, 2021
(86) PCT No.: PCT/JP2021/031081

§ 371 Date: Dec. 15, 2023

(51) Int. Cl. H01L 23/13; H01L 23/00; H01L 23/31

(52) U.S. Cl. CPC H01L 23/13; H01L 23/3121; H01L 24/48; H01L 24/94; H01L 2224/48155; H01L 2224/94; H01L 2924/3511; H01L 2924/3512

(57) ABSTRACT

Provided here are: a board; a cavity region therein having an opening created on a front side of a central portion of the board; a back-side conductor that is formed for the board to provide a bottom portion of the cavity region; a semiconductor chip mounted on the back-side conductor; and a mold material that covers the semiconductor chip and the board; wherein the mold material has a portion on the front side of the board and a portion on the back side thereof that are interconnected through at least one hole provided in the board, thereby to prevent failures such as a deformation, a crack, etc. of the board; and to reduce the warpage of the board to prevent the mold material from being peeled off therefrom.

### TECHNICAL FIELD

The present application relates to a semiconductor device.

### BACKGROUND ART

In general, there are such mold packages that are obtained by mounting many semiconductor chips on a circuit board, encapsulating these components wholly with a resin, and then dividing the encapsulated product by dicing into individual pieces with intended sizes. As a manufacturing method of such semiconductor devices, a transfer molding process is widely used. Meanwhile, the generation of heat by a semiconductor chip increases as its output power increases, so that its circuit board is required to have enhanced heat dissipation capability. However, in many cases, the circuit board uses a resin or ceramic, so that its heat dissipation capability is poor.

In order to enhance the heat dissipation capability, it is effective to employ a cavity structure to thereby cut down the thermal resistance of the part corresponding to the circuit board. Even in this case, since a Cu conductor generally used in a circuit board subject to high density interconnections has a thickness that is as thin as around 30 μm, it is difficult to spread out heat sufficiently, resulting in limited heat dissipation capability.

In order to further enhance heat dissipation capability, there is a method of increasing the thickness of a back-side conductor so that the conductor serves as a heatsink. In the case where the thickness of the back-side conductor is so increased, at the time the board is set in a die for the transfer molding process, the gap between the bottom face of the board and the die becomes larger. In the case where the interval between back-side conductors is wide, if the gap between the bottom face of the board and the die is large, the deformation amount of the board due to molding pressure at the time of the transfer molding process becomes larger, so that a failure may occur, for example, a crack may be generated. This is particularly significant in an area where an inter-section point of dicing lines is located, because the support distance by the back-side conductors becomes wider.

As a countermeasure, there is conceivable a method in which another back-side conductor is disposed additionally in each place corresponding to the wide interval between the back-side conductors, for example, in each region where the intersection point of dicing lines is located, to thereby prevent the interval between the back-side conductors from being so wide. However, this results in a very large load on the dicing blade when such a thick back-side conductor is to be cut. Further, there is concern about rapid progression of abrasion of the dicing blade and breakage of the dicing blade. Thus, it is difficult to dispose the other back-side conductor at the intersection point of the dicing lines.

For dealing with this, in Patent Document 1, a method is disclosed in which support pins are provided on the molding die in respective areas corresponding to the intersection points of dicing lines, to thereby support the circuit board, so that the board is prevented from being deformed.

### CITATION LIST

### Patent Document Patent Document 1: Japanese Patent Application Laid-open No. 2003-234365 (Paragraph 0011; FIG. 3)

### SUMMARY OF THE INVENTION

### Problems to be Solved by the Invention

However, according to the method in Patent Document 1, it is required to apply special machining to the molding die and thus, there is a problem that the cost of the die increases. Further, since the support pins have to be located in conformity with the size of each product piece, there is a problem in terms of cost that, for every size of the piece, a cost for newly fabricating the corresponding die is necessary. Furthermore, although the thickness of the back-side conductor has manufacturing fluctuation, the height of the support pin is fixed, so that there is a technical problem that the support pin cannot follow up the fluctuation of the thickness of the back-side conductor.

This application has been made to solve the problem as described above, and an object thereof is to provide a semiconductor device having high heat dissipation capability, at a low cost and easily.

### Means for Solving the Problems

A semiconductor device disclosed in this application is characterized by comprising: a board; a cavity therein having an opening created on a front side of a central portion of the board; a back-side conductor that is formed for the board to provide a bottom face of the cavity; a semiconductor chip mounted on the back-side conductor; and a mold material that covers the semiconductor chip and the board; wherein the mold material has a portion on the front side of the board and a portion on the back side thereof that are interconnected through at least one hole provided in the board.

### Effect of the Invention

According to this application, since a portion of the mold material on the front side of the board and a portion thereof on the back side of the board, are interconnected through at least one hole provided in the board, it is possible to prevent failures such as a deformation, a crack, etc. of the board. Further, it is possible to reduce the warpage of the board, and thus to prevent the mold material from being peeled off from the board.

### BRIEF DESCRIPTION OF THE DRAWINGS

FIG. 1A and FIG. 1B are a set of a back view and a cross-sectional view for showing a configuration of a semiconductor device according to Embodiment 1.

FIG. 2A and FIG. 2B are set of a back view and a cross-sectional view for showing a configuration of another semi-conductor device according to Embodiment 1.

FIG. 3A, FIG. 3B and FIG. 3C are a set of cross-sectional views each showing an exemplary step for manufacturing the semi-conductor device according to Embodiment 1.

FIG. 4A, FIG. 4B and FIG. 4C are a set of a back view and cross-sectional views for showing a configuration of a semiconductor device according to Embodiment 2.

FIG. 5A, FIG. 5B and FIG. 5C are a set of a back view and cross-sectional views for showing a configuration of another semi-conductor device according to Embodiment 2.

FIG. 6A and FIG. 6B are a set of a back view and a cross-sectional view for showing a configuration of a semiconductor device according to Embodiment 3.

FIG. 7A and FIG. 7B are a set of a back view and a cross-sectional view for showing a configuration of another semi-conductor device according to Embodiment 3.

FIG. 8A and FIG. 8B are a set of a back view and a cross-sectional view for showing a configuration of another semi-conductor device according to Embodiment 3.

FIG. 9A and FIG. 9B are a set of a back view and a cross-sectional view for showing a configuration of another semi-conductor device according to Embodiment 3.

FIG. 10A and FIG. 10B are a set of a back view and a cross-sectional view for showing a configuration of a semi-conductor device according to Embodiment 4.

FIG. 11A and FIG. 11B are a set of a back view and a cross-sectional view for showing a configuration of another semiconductor device according to Embodiment 4.

FIG. 12A and FIG. 12B are a set of a back view and a cross-sectional view for showing a configuration of another semiconductor device according to Embodiment 4.

FIG. 13A and FIG. 13B are a set of a back view and a cross-sectional view for showing a configuration of a semi-conductor device according to Embodiment 5.

FIG. 14A and FIG. 14B are a set of a back view and a cross-sectional view for showing a configuration of a semi-conductor device according to Embodiment 6.

FIG. 15A and FIG. 15B are a set of a back view and a cross-sectional view showing a configuration of a semi-conductor device according to Embodiment 7.

FIG. 16A, FIG. 16B, FIG. 16C and FIG. 16D are a set of a top view, a back view and cross-sectional views for showing a configuration of the semiconductor device according to Embodiment 7.

FIG. 17A and FIG. 17B are a set of a back view and a cross-sectional view for showing a configuration of another semiconductor device according to Embodiment 7.

### MODES FOR CARRYING OUT THE INVENTION

### Embodiment 1

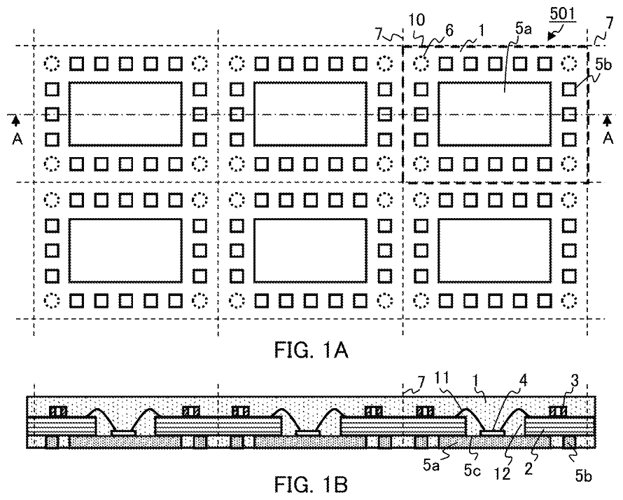

FIG. 1A and FIG. 1B are a set of diagrams for showing a configuration of a semiconductor device 501 according to Embodiment 1 of this application. FIG. 1A is a back view of the semiconductor devices 501, and FIG. 1B is an A-A arrow sectional view of FIG. 1A. As shown in FIG. 1A and FIG. 1B, the semiconductor devices 501 each comprises a semiconductor chip 4, electronic components 3, a board 2, back-side conductors 5a, 5b, wires 11 and a mold material 1.

In a cavity structure that is established by the board 2 and the back-side conductor 5a, the semiconductor chip 4 is mounted on the back-side conductor 5a that forms a bottom portion 5c of a cavity region (concave region) 12. The back-side conductors 5a, 5b have a thickness of 50 μm or more (more preferably, 100 μm or more).

In the board 2, four holes 6 are provided in respective areas near the four corner portions of a rectangular piece 10. Each hole 6 may be created perpendicularly or obliquely to the board 2. Note that, in Embodiment 1, the shape of the hole 6 in cross-section across the hole extending direction is a circular shape; however, this is not limitative. The shapes, the sizes, the number and the located positions of the holes 6 may be set arbitrarily. Further, multiple types of shapes, multiple types of sizes, or multiple types of location patterns, may be used in combination.

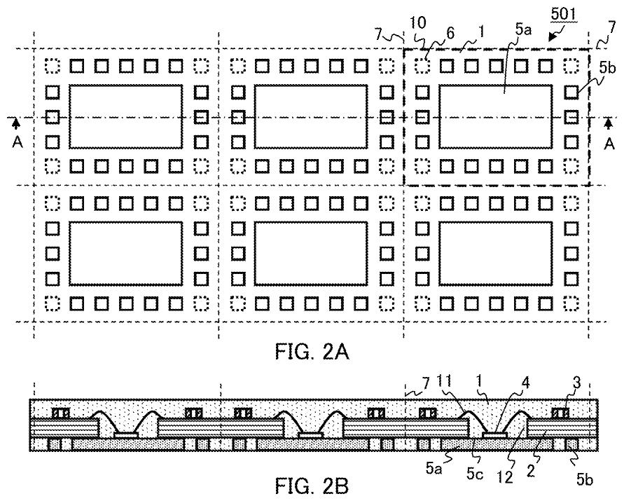

FIG. 2 is a set of diagrams for showing a configuration of another semiconductor device 501 according to Embodiment 1 of this application. As shown in FIG. 2, the shape of each of holes 6 in cross-section across the hole extending direction is a square shape. The other configuration is the same as what is shown in FIG. 1.

When the board 2 or the like is subjected to transfer molding using the mold material 1, a molding pressure of around 10 MPa is applied usually. Due to this molding pressure, there are cases where failures, such as a deformation, a crack, etc. occurs in the board 2. According to this application, because of the provision of the hole 6, there is provided a passage for charging the mold material 1 toward the back side of the board 2.

Accordingly, the molding pressure is applied in a state in which the front side and the back side of the board 2 are filled with the mold material 1, and thus the molding pressure is applied to the board equally from its upper and lower sides, so that it becomes possible to prevent failures such as a deformation, a crack, etc. of the board 2. Heretofore, the molding pressure could not be increased beyond a certain level in order to prevent failures such as a deformation, a crack, etc. of the board 2. However, according to this application, it is possible to increase the molding pressure as compared with the conventional method, so that the occurrence of a void and an unfilled state can be prevented.

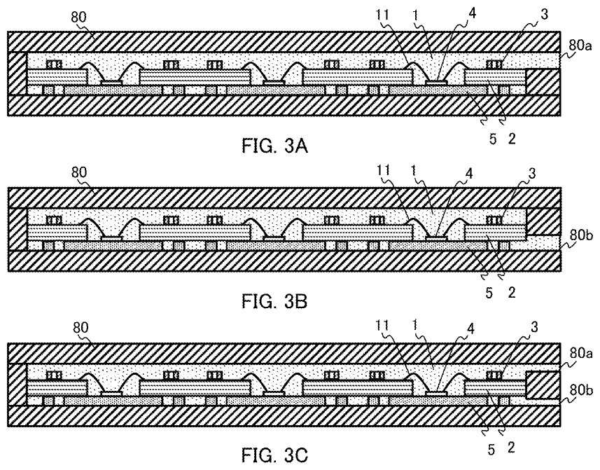

Furthermore, since the mold material 1 can move between the upper and lower sides of the board 2 through the hole 6, it is possible to select, instead of a method as shown in FIG. 3A in which the mold material 1 is injected from an inlet 80a of a molding die 80 that is placed on the front side of the board 2, a method as shown in FIG. 3B in which the mold material 1 is injected from an inlet 80b of the molding die that is placed on the back side of the board 2. Further, it is also possible to select a method as shown in FIG. 3C in which the mold material 1 is injected concurrently from the inlet 80a and the inlet 80b placed on the front side and the back side of the board 2, respectively.

It is possible not only to freely select the position of the inlet of the molding die in the above manner, but also to suppress, by injecting the mold material 1 from the inlet 80b on the back side of the board 2 and thus by changing the injection direction of the mold material 1, wire sweep and wire inclination that may occur when the mold material 1 is injected laterally to the wires 11. Furthermore, when it is required to reduce the injection time because of a high curing rate of the mold material 1 or something like that, it is possible to reduce the injection time by injecting the mold material 1 concurrently from the front side and the back side of the board 2.

Further, it is possible to solve, at the same time, the cost problem and the technical problem according to the support pin system disclosed in Patent Document 1. In terms of cost, since machining to the die, such as the formation of the support pins or the like is unnecessary, the machining cost of the die can be reduced. In terms of technical matter, since the mold material 1 is filled on the back side, it becomes possible to follow up the fluctuation of the thickness of the back-side conductor. Further, it is possible to reduce the warpage of the board since the mold material 1 is placed on the front and back sides thereof. Furthermore, since such a configuration is established in which, with respect to the mold material 1, its portion on the front side of the board 2 and its portion on the back side thereof are integrated with each other through the hole 6, it is possible to prevent the mold material from being peeled off from the board.

As described above, the semiconductor device 501 according to Embodiment 1 comprises: the board 2; the cavity region 12 therein having an opening created on the front side of a central portion of the board 2; the back-side conductor 5a that is formed for the board 2 to provide the bottom portion 5c of the cavity region 12; the semiconductor chip 4 mounted on the back-side conductor 5a; and the mold material 1 that covers the semiconductor chip 4 and the board 2; wherein the mold material 1 has a portion on the front side of the board 2 and a portion on the back side thereof that are interconnected through at least one hole 6 provided in the board 2. Thus, it is possible to prevent failures such as a deformation, a crack, etc. of the board. Further, it is possible to reduce the warpage of the board, and thus to prevent the mold material from being peeled off from the board.

### Embodiment 2

In Embodiment 1, the description has been made on the cases where the holes 6 are provided in the respective areas near the four corner portions of the piece 10, whereas in Embodiment 2, description will be made on cases where holes are provided on dicing lines 7.

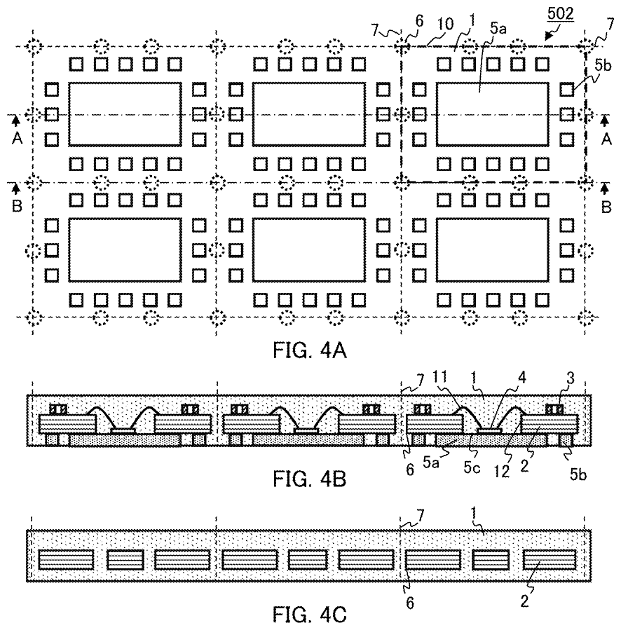

FIG. 4A, FIG. 4B and FIG. 4C are a set of schematic diagrams for showing a configuration of a semiconductor device 502 according to Embodiment 2 of this application. FIG. 4A is a back view of the semiconductor devices 502, and FIG. 4B is an A-A arrow sectional view of FIG. 4A and FIG. 4C is a B-B arrow sectional view of FIG. 4A. As shown in FIG. 4A, FIG. 4B and FIG. 4C, according to the semiconductor device 502, the holes 6 are provided on the dicing lines 7 of the board 2. The configuration of the semiconductor device 502 according to Embodiment 2 other than the above, is similar to what is included in the semiconductor device 501 according to Embodiment 1, so that, to the equivalent parts, the same reference numerals are given and the description thereof will be omitted.

In Embodiment 2, four holes 6 are provided at four corner portions of the rectangular piece 10, two holes 6 are provided at each of the long sides of that piece, and one hole 6 is provided at each of the short sides of that piece; however, this is not limitative. The shapes, the sizes, the number and the located positions of the holes 6 may be set arbitrarily. Further, multiple types of shapes, multiple types of sizes, or multiple types of location patterns, may be used in combination.

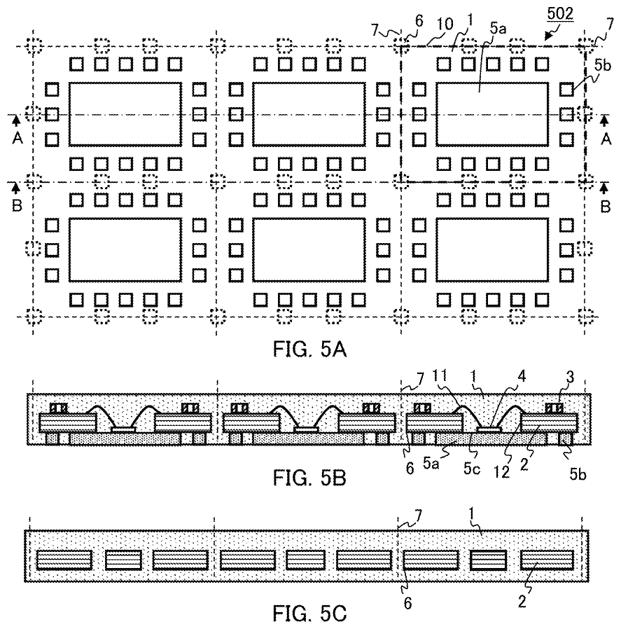

FIG. 5A, FIG. 5B and FIG. 5C set of diagrams for showing a configuration of another semiconductor device 502 according to Embodiment 2 of this application. As shown in FIGS. 5A-C, the shape of each of the holes 6 in cross-section across the hole extending direction is a square shape. The other configuration is similar to what is shown in FIGS. 4A-C.

An edge portion of the piece 10 formed by dicing is likely to become a peeling start point. In Embodiment 2, as shown in FIG. 4C and FIG. 5C, at each of edge portions of the piece 10 that is likely to become a peeling start point, such a configuration is established in which the mold material 1 serves to clamp the front and back sides of the board 2. This makes it possible to achieve an enhanced effect of preventing peeling between the mold material 1 and the board 2.

As described above, in the semiconductor device 502 according to Embodiment 2, the holes 6 are created on the dicing lines 7. Thus, in addition to achieving the effect according to Embodiment 1, it is possible to achieve an enhanced effect of preventing peeling between the mold material and the board.

### Embodiment 3

In Embodiment 2, the description has been made on the cases where the holes 6 are created at given positions on the dicing lines 7 corresponding to the long sides and shorts sides of the piece 10 formed by dicing, whereas in Embodiment 3, description will be made on cases where holes are created thereon to be displaced from the positions of the back-side conductors 5b.

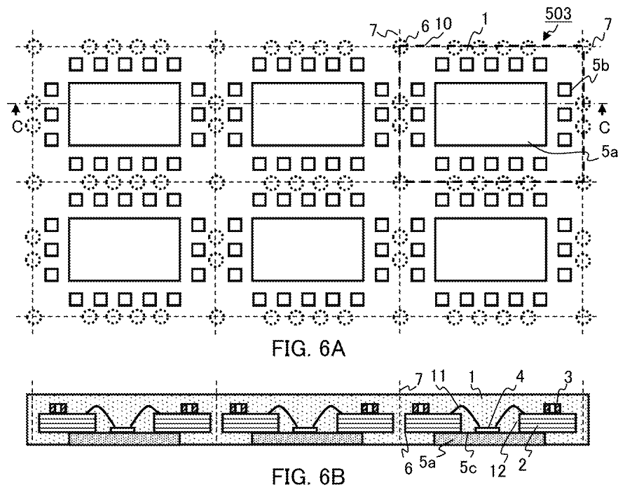

FIG. 6A and FIG. 6B are a set of diagrams for showing a configuration of a semiconductor device 503 according to Embodiment 3 of this application. FIG. 6A is a back view of the semiconductor devices 503, and FIG. 6B is a C-C arrow sectional view of FIG. 6A. As shown in FIG. 6A and FIG. 6B, according to the semiconductor device 503, holes 6 are provided on the dicing lines 7 of the board 2 so as to be displaced from positions corresponding to the positions of the back-side conductors 5b. The configuration of the semiconductor device 503 according to Embodiment 3 other than the above, is similar to what is included in the semiconductor device 501 according to Embodiment 1, so that, to the equivalent parts, the same reference numerals are given and the description thereof will be omitted.

In Embodiment 3, four holes 6 are provided at four corner portions of the rectangular piece 10, four holes 6 are provided at each of the long sides of that piece, and two holes 6 are provided at each of the short sides of that piece; however, this is not limitative. The shapes, the sizes, the number and the located positions of the holes 6 may be set arbitrarily.

Further, multiple types of shapes, multiple types of sizes, or multiple types of location patterns, may be used in combination.

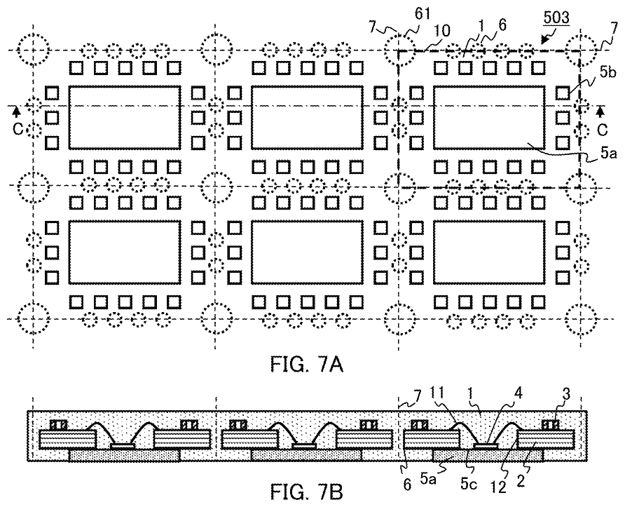

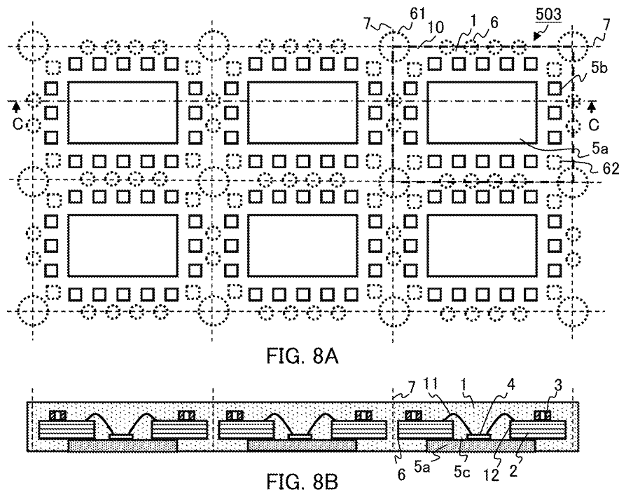

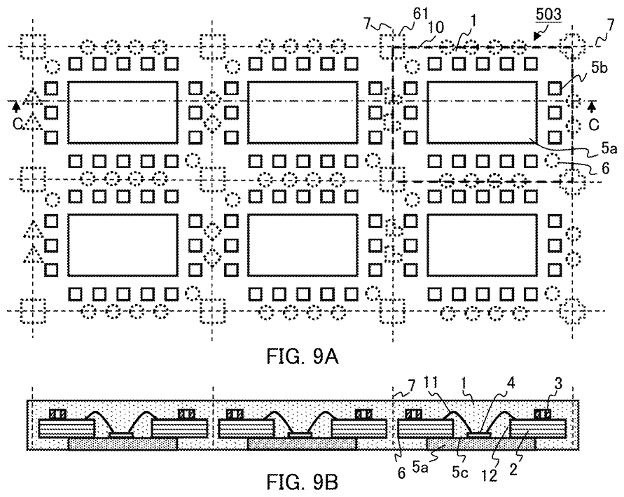

FIG. 7A, FIG. 7B, FIG. 8A, FIG. 8B, FIG. 9A and FIG. 9B are each a set of diagrams for showing a configuration of another semiconductor device 503 according to Embodiment 3 of this application. In FIGS. 7A-B, only the diameter of holes 61 at the four corner portions of the piece 10 is made larger than the diameter of the other holes 6. In FIGS. 8A-B, in addition to the above, square holes 62 are added in respective areas near the four corner portions of the piece 10. In FIGS. 9A-B, the diameter of holes 61 at the four corner portions of the piece 10 is made larger than that of the other holes 6 and the shape of each of these holes in cross-section across the hole extending direction is a square shape or a cross shape, and further, the shapes of holes 6 at the short sides include not only the circular shape, but also a triangular shape, a diamond shape or an L-shape. The other configuration is similar to what is shown in FIGS. 6A-B.

In the case where the mold material 1 is charged from the upper side of the board 2 into the back side of the board 2 through the hole 6, if the back-side conductor 5b is placed near that hole 6, because of the back-side conductor 5b, the mold material 1 will be inhibited from spreading horizontally. For that reason, the positions of the hole 6 and the back-side conductor 5b are displaced from each other. This makes it possible to prevent such cases where, because of the back-side conductor 5b, the mold material 1 is inhibited from spreading horizontally.

As described above, in the semiconductor device 503 according to Embodiment 3, the holes 6 are provided on the dicing lines 7 so as to be displaced from positions corresponding to the respective positions of the back-side conductors 5b. Thus, in addition to achieving the effect according to Embodiment 2, it is possible to enhance the fillability of the mold material.

### Embodiment 4

In Embodiment 2 and Embodiment 3, the description has been made on the cases where the holes each having a circular shape, a square shape or a cross shape are provided on the dicing lines 7, whereas in Embodiment 4, description will be made on cases where holes each having a slit shape are provided.

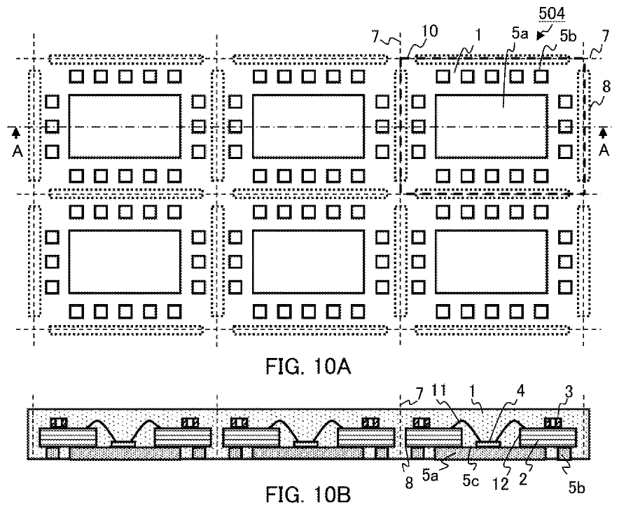

FIG. 10A and FIG. 10B are a set of diagrams for showing a configuration of a semiconductor device 504 according to Embodiment 4 of this application. FIG. 10A is a back view of the semiconductor devices 504, and FIG. 10B is an A-A arrow sectional view of FIG. 10A. As shown in FIG. 10A and FIG. 10B, the semiconductor device 504 has slit holes 8 each having a rectangular shape in cross-section across the hole extending direction, and the slit holes 8 are provided on the dicing lines 7 of the board 2. The configuration of the semiconductor device 504 according to Embodiment 4 other than the above is similar to what is included in the semiconductor device 501 according to Embodiment 1, so that, to the equivalent parts, the same reference numerals are given and the description thereof will be omitted.

It is noted that, in Embodiment 4, the slit holes 8 are provided on the dicing lines 7; however, they may be provided within an area to be provided as a piece. The shapes, the sizes, the number and the located positions of the slit holes 8 may be set arbitrarily, and multiple types of shapes, multiple types of sizes, or multiple types of location patterns, may be used in combination.

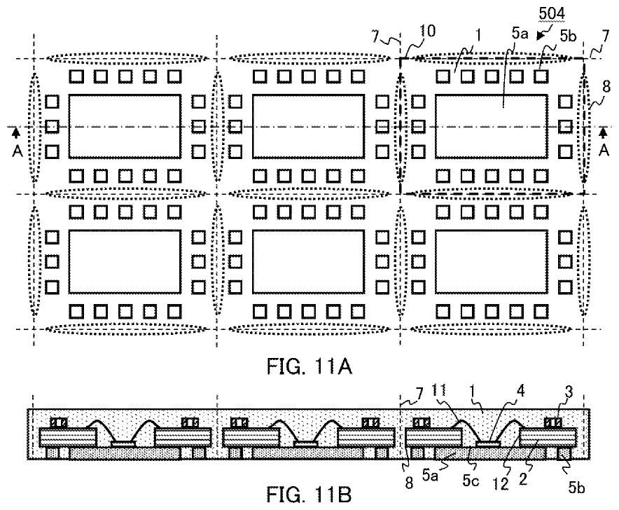

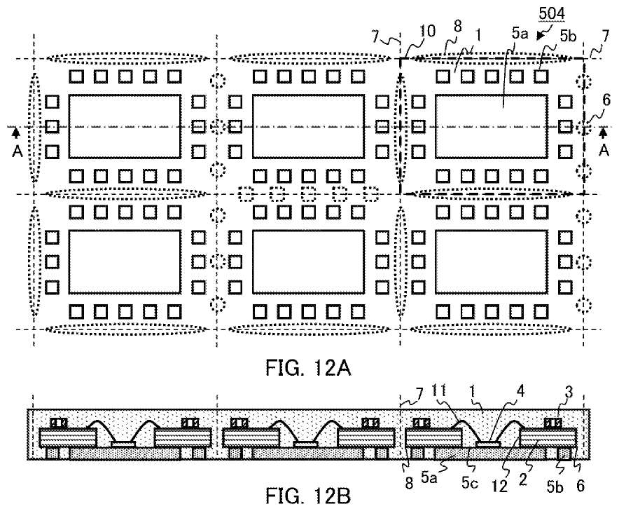

FIG. 11A, FIG. 11B, FIG. 12A and FIG. 12B are each a set of diagrams for showing a configuration of another semiconductor device 504 according to Embodiment 4 of this application. In FIGS. 11A-B, the shape of the slit hole 8 in cross-section across the hole extending direction is an elliptical shape. In FIGS. 12A-B, not only the silt hole 8 but also a circular hole 6 is used at the short sides of the pieces 10, and at the long sides thereof, a square hole 6 is also used. The other configuration is similar to what is shown in FIGS. 10A-B.

Because of the use of the slit hole 8, such a configuration in which the mold material 1 serves to clamp the front and back sides of the board 2 at an edge portion of the piece 10 that is likely to become a peeling start point, can be enlarged as compared with the case of using a circular or like hole 6. This makes it possible to further enhance the effect of preventing peeling between the mold material 1 and the board 2.

As described above, in the semiconductor device 504 according to Embodiment 4, the slit hole 8 is used. Thus, in addition to achieving the effect according to Embodiment 3, it is possible not only to enhance the fillability of the mold material because of the enlargement of the flow passage of the mold material in a front-back direction with respect to the board, but also to enhance the effect of preventing peeling between the mold material and the board.

### Embodiment 5

In Embodiment 4, description has been made on the cases where the slit holes 8 are provided at the short sides and the long sides of the piece 10, whereas in Embodiment 5, description will be made on a case where slit holes that also cover the corner portions of the piece 10 are provided.

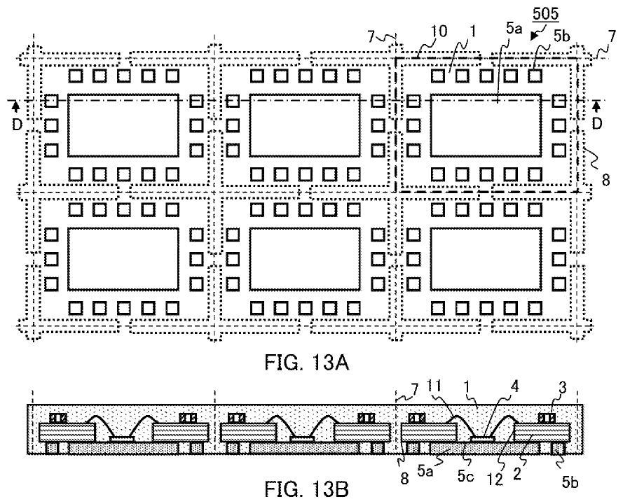

FIG. 13A and FIG. 13B are a set of diagrams for showing a configuration of a semiconductor device 505 according to Embodiment 5 of this application. FIG. 13A is a back view of the semiconductor devices 505, and FIG. 13B is a D-D arrow sectional view of FIG. 13A. As shown in FIG. 13A and FIG. 13B, according to the semiconductor devices 505, slit holes 8 each having a cross shape as a shape in cross-section across the hole extending direction, are provided on the dicing lines 7 of the board 2 so as to cover the corner portions of the pieces 10. The configuration of the semiconductor device 505 according to Embodiment 5 other than the above, is similar to what is included in the semiconductor device 501 according to Embodiment 1, so that, to the equivalent parts, the same reference numerals are given and the description thereof will be omitted.

The shapes, the sizes, the number and the located positions of the slit holes 8 may be set arbitrarily, and multiple types of shapes, multiple types of sizes, or multiple types of location patterns, may be used in combination.

Since the slit hole 8 is provided so as to cover the corner portion of the piece 10, such a structure in which the mold material 1 serves to clamp the front and back sides of the board 2 can be established even at the corner portion of the piece 10 that is likely to become a peeling start point. This makes it possible to further enhance the effect of preventing peeling between the mold material 1 and the board 2.

As described above, in the semiconductor device 505 according to Embodiment 5, the silt hole 8 is provided so as to cover the corner portion of the board 2. Thus, in addition to achieving the effect according to Embodiment 4, it is possible, even at the corner portion that is likely to become a peeling start point, to enhance the effect of preventing the peeling.

### Embodiment 6

In Embodiment 6, description will be made on a case where a tunnel is further provided in the board.

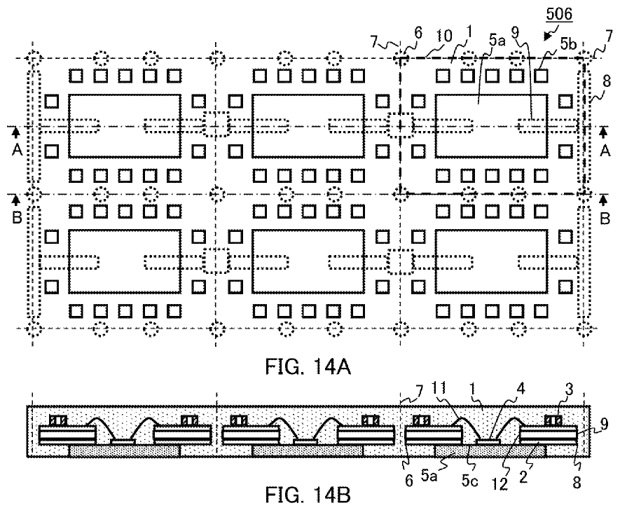

FIG. 14A and FIG. 14B are a set of diagrams for showing a configuration of a semiconductor device 506 according to Embodiment 6 of this application. FIG. 14A is a back view of the semiconductor devices 506, and FIG. 14B is an A-A arrow sectional view of FIG. 14A. As shown in FIG. 14A and FIG. 14B, according to the semiconductor device 506, tunnels (through passages) 9 are provided horizontally inside the board 2. The tunnels 9 communicate a slit hole 8 with the cavity region 12 and communicate a hole 6 with the cavity region 12. The configuration of the semiconductor device 506 according to Embodiment 6 other than the above, is similar to what is included in the semiconductor device 501 according to Embodiment 1, so that, to the equivalent parts, the same reference numerals are given and the description thereof will be omitted. It is noted that, in Embodiment 6, the slit

hole 8 is communicated with the cavity region 12 and the hole 6 is communicated with the cavity region 12; however, the hole 6 and the slit hole 8 may be communicated with each other. Further, there are provided the slit hole 8 and the hole 6; however, only one of them may be provided. The shapes, the sizes, the number and the located positions of the holes 6, the slit holes 8 or the tunnels 9 may be set arbitrarily, and multiple types of shapes, multiple types of sizes, or multiple types of location patterns, may be used in combination.

Because the mold material 1 may be filled toward the cavity region 12 through the tunnel 9 inside the board 2, the number of filling passages of the mold material 1 toward the cavity region 12 increases, so that the fillability of the mold material 1 to the cavity region 12 is enhanced.

As described above, in the semiconductor device 506 according to Embodiment 6, the tunnel 9 that horizontally communicates the hole 6 or the slit hole 8 with the cavity region 12 is provided inside the board 2. Thus, in addition to achieving the effect according to Embodiment 5, it is possible to enhance the fillability of the mold material to the cavity region.

### Embodiment 7

In Embodiment 7, description will be made on a case where, in association with the cavity region 12, an interspace is formed between the board and the back-side conductor.

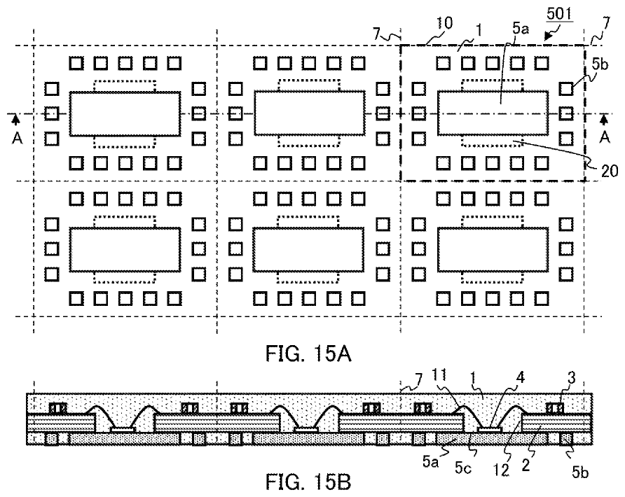

FIG. 15A and FIG. 15B are a set of diagrams for showing a configuration of a semiconductor device 507 according to Embodiment 7 of this application. FIG. 15A is a back view of the semiconductor devices 507, and FIG. 15B is an A-A arrow sectional view of FIG. 15A.

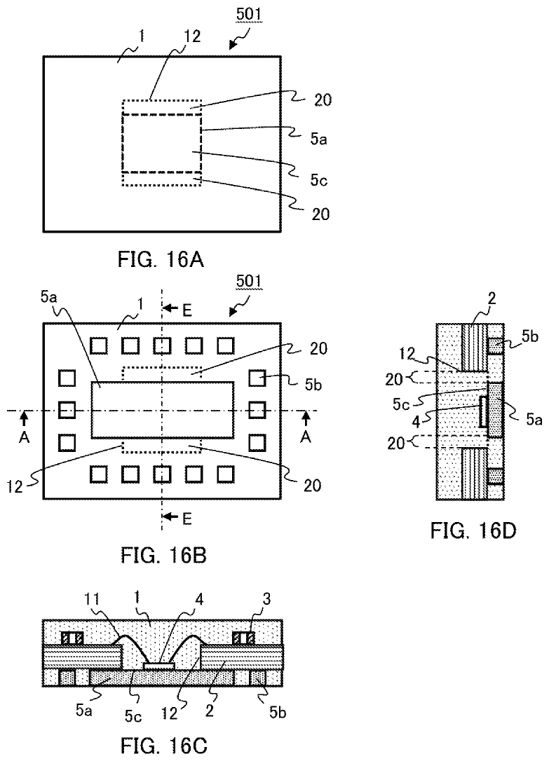

FIG. 16A, FIG. 16B, FIG. 16C and FIG. 16D are a set of enlarged diagrams about a piece 10 in FIGS. 15A-B. FIG. 16A is a top view of the piece 10 in FIGS. 15A-B. FIG. 16B is a back view of the piece 10 in FIGS. 15A-B. FIG. 16C is an A-A sectional view of FIG. 16B. FIG. 16D is an E-E arrow sectional view of FIG. 16B.

As shown in FIGS. 15A-B and FIGS. 16A-D, according to the semiconductor device 507, in association with the cavity region 12, interspaces are formed between the board 2 and the back-side conductor 5a, to thereby create slit holes 20. The configuration of the semiconductor device 507 according to Embodiment 7 other than the above, is similar to what is included in the semiconductor device 501 according to Embodiment 1, so that, to the equivalent parts, the same reference numerals are given and the description thereof will be omitted.

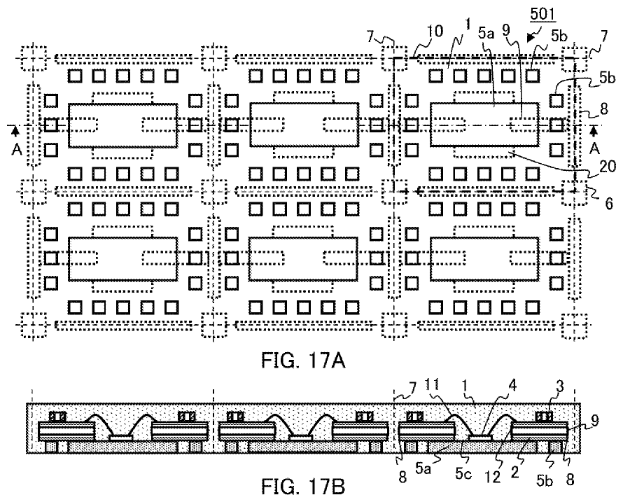

The shapes, the sizes, the number and the located positions of the slit holes 20 in association with the cavity region 12 may be set arbitrarily, and multiple types of shapes, multiple types of sizes, or multiple types of location patterns, may be used in combination. As shown in FIG. 17A and FIG. 17B, these slit holes may be used in any given combination with the hole 6, the slit hole 8 and/or the tunnel 9.

Since the slit holes 20 are provided adjacent to the bottom portion 12a of the cavity region 12 where an unfilled state of the mold material 1 is likely to occur, to thereby establish flow passages of the mold material 1, it is possible to enhance the fillability of the mold material 1 to the cavity region 12.

As described above, in the semiconductor device 507 according to Embodiment 7, the slit holes 20 are provided adjacent to the bottom portion 12a of the cavity region 12. Thus, it is possible to enhance the fillability of the mold material to the cavity region. In this application, a variety of exemplary

embodiments and examples are described; however, every characteristic, configuration or function that is described in one or more embodiments, is not limited to being applied to a specific embodiment, and may be applied singularly or in any of various combinations thereof to another embodiment. Accordingly, an infinite number of modified examples that are not exemplified here are supposed within the technical scope disclosed in the description of this application. For example, such cases shall be included where at least one configuration element is modified; where at least one configuration element added is or omitted; and furthermore, where at least one configuration element is extracted and combined with a configuration element of another embodiment.

### DESCRIPTION OF REFERENCE NUMERALS and SIGNS

1: mold material, 2: board, 4: semiconductor chip, 5a: back-side conductor, 5c: bottom portion, 6: hole, 7: dicing line, 8: slit hole, 12: cavity region, 20: slit hole, 61, 62: hole, 501, 502, 503, 504, 505, 506, 507: semiconductor device.

1-8. (canceled)

9. A semiconductor device comprising:
a board;
a cavity therein having an opening created on a front side of a central portion of the board;
a back-side conductor that is formed for the board to provide a bottom face of the cavity;
a semiconductor chip mounted on the back-side conductor; and
a mold material that covers the semiconductor chip and the board;
wherein the mold material has a portion on the front side of the board and a portion on the back side thereof that are interconnected through at least one hole provided in the board; and
wherein the hole is created on a dicing line.

10. The semiconductor device as set forth in claim 9, wherein the hole is provided on the dicing line so as to be displaced from a position corresponding to a position of another back-side conductor.

11. The semiconductor device as set forth in claim 9, wherein the hole is configured to cover a corner portion of the board that is rectangular.

12. The semiconductor device as set forth in claim 10, wherein the hole is configured to cover a corner portion of the board that is rectangular.

13. The semiconductor device as set forth in claim 9, wherein another hole is further provided adjacent to a bottom portion of the cavity.

14. The semiconductor device as set forth in claim 10, wherein another hole is further provided adjacent to a bottom portion of the cavity.

15. The semiconductor device as set forth in claim 11, wherein another hole is further provided adjacent to a bottom portion of the cavity.

16. The semiconductor device as set forth in claim 9, wherein another hole is further created in an area near a corner portion of the board that is rectangular.

17. The semiconductor device as set forth in claim 10, wherein another hole is further created in an area near a corner portion of the board that is rectangular.

18. The semiconductor device as set forth in claim 11, wherein another hole is further created in an area near a corner portion of the board that is rectangular.

19. The semiconductor device as set forth in claim 9, wherein the hole has a shape in cross-section that is a circular shape, a square shape, a cross shape or an L-shape.

20. The semiconductor device as set forth in claim 10, wherein the hole has a shape in cross-section that is a circular shape, a square shape, a cross shape or an L-shape.

21. The semiconductor device as set forth in claim 11, wherein the hole has a shape in cross-section that is a circular shape, a square shape, a cross shape or an L-shape.

22. The semiconductor device as set forth in claim 9, wherein the hole has a shape in cross-section that is a slit-like shape.

23. The semiconductor device as set forth in claim 10, wherein the hole has a shape in cross-section that is a slit-like shape.

24. The semiconductor device as set forth in claim 11, wherein the hole has a shape in cross-section that is a slit-like shape.

25. The semiconductor device as set forth in claim 9, wherein a through passage that horizontally communicates the hole with the cavity is formed inside the board.

26. The semiconductor device as set forth in claim 10, wherein a through passage that horizontally communicates the hole with the cavity is formed inside the board.

27. The semiconductor device as set forth in claim 11, wherein a through passage that horizontally communicates the hole with the cavity is formed inside the board.
